(19) United States
(12) Patent Application Publication
(10) Pub. No.: US 2017/0160012 A1
(43) Pub. Date: Jun. 8, 2017

(54) SEMICONDUCTOR ANNEALING APPARATUS

(71) Applicant: Mitsubishi Electric Corporation, Tokyo (JP)

(72) Inventors: Kazuo KOBAYASHI, Tokyo (JP); Masaaki IKEGAMI, Tokyo (JP)

(73) Assignee: Mitsubishi Electric Corporation, Tokyo (JP)

(21) Appl. No.: 15/323,769

(22) PCT Filed: Sep. 8, 2014
(86) PCT No.: PCT/JP2014/073700

§ 371 Date: Jan. 4, 2017

(51) Int. Cl. F27D 5/00; F27D 7/06; H01L 21/265

(52) U.S. Cl. CPC F27D 5/0037; H01L 21/26513; F27D 7/06; F27D 2007/063

(57) ABSTRACT

A semiconductor annealing apparatus includes: a chamber; a tube provided inside the chamber; a wafer boat provided inside the tube so as to be able to advance into and retreat out of the tube; a loading area in which the wafer boat is positioned when the wafer boat retreats out of the tube; hydrocarbon supply means for supplying hydrocarbon gas into the tube; heating means for heating the inside of the tube; and oxygen supply means for supplying oxygen into the tube. The tube is made of sapphire or is made of SiC and formed by all-CVD, and wherein the wafer boat is made of sapphire or is made of SiC and formed by all-CVD.

### FIELD

The present invention relates to a semiconductor annealing apparatus.

### BACKGROUND

A semiconductor annealing apparatus for performing annealing on a silicon carbide (SiC) wafer, for example, as shown in JP 2009-260115 A, is known. With one semiconductor annealing apparatus according to the above-mentioned publication, a process including forming of a graphite film on a SiC wafer, high-temperature annealing on the SiC wafer and removal of the graphite film can be performed.

### CITATION LIST

### Patent Literature

[PTL1]JP 2009-260115 A

### SUMMARY

### Technical Problem

In a semiconductor annealing apparatus, jigs such as a tube and a wafer boat are provided. These jigs are required to have high heat resistance such as to be able to endure temperatures in a temperature range for annealing. Conventionally, a jig having, for example, a frame formed of a basic material including SiC and a high-purity SiC coating film formed on the frame by CVD is used as a jig for use in apparatuses for annealing SiC wafers. A SiC wafer is annealed at a high temperature equal to or higher than 1500° C. A SiC wafer needs annealing at a markedly high temperature in comparison with a silicon wafer. In such a high-temperature range, a problem newly arises that a foreign material contained in the basic material contaminates inner portions of the semiconductor annealing apparatus. For example, if a heavy metal is contained in the SiC basic material, diffusion of this heavy metal occurs, resulting in a contamination in the semiconductor annealing apparatus. There is a problem that this contamination badly influences the quality of the SiC wafer.

The present invention has been achieved to solve the above-described problems, and an object of the present invention is to provide a semiconductor annealing apparatus capable of inhibiting contamination in a chamber.

### Solution to Problem

A semiconductor annealing apparatus according to the present invention includes: a chamber; a tube provided inside the chamber; a wafer boat provided inside the tube so as to be able to advance into and retreat out of the tube; a loading area in which the wafer boat is positioned when the wafer boat retreats out of the tube; hydrocarbon supply means for supplying hydrocarbon gas into the tube; heating means for heating the inside of the tube; and oxygen supply means for supplying oxygen into the tube. The tube is made of sapphire or is made of SiC and formed by all-CVD, and wherein the wafer boat is made of sapphire or is made of SiC and formed by all-CVD.

### Advantageous Effect of Invention

According to the present invention, a tube and a wafer boat are formed so as to be capable of preventing contamination even in a high-temperature range, thus enabling inhibition of contamination in the chamber.

### BRIEF DESCRIPTION OF DRAWINGS

FIG. 1 shows a SiC wafer having a surface capped with a carbon protective film.

FIG. 2 is a diagram showing a semiconductor annealing apparatus according to an embodiment of the present invention.

FIG. 3 is a diagram showing a semiconductor annealing apparatus according to an embodiment of the present invention.

FIG. 4 is a diagram schematically showing a gas system according to an embodiment of the present invention.

FIG. 5 is a flowchart showing a process in a semiconductor annealing method according to the embodiment of the present invention.

### DESCRIPTION OF EMBODIMENT

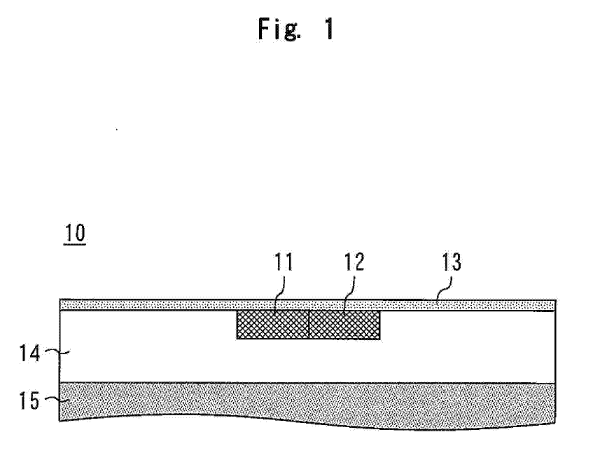

FIG. 1 shows a SiC wafer 10 having P-type implanted layers 11 and 12 formed on a silicon carbide (SiC) epitaxial layer 14 grown on a substrate 15 and having a surface capped with a carbon protective film 13. It is known that silicon carbide has a small impurity diffusion coefficient, that is, a dopant species cannot ordinarily diffuse easily in a SiC wafer. There is, therefore, a need for annealing at 1500° C. or higher for activation of an implanted species after an implantation process is performed on the SiC wafer 10.

That is, a heat treatment for activating the P-type implanted layers 11 and 12 shown in FIG. 1 is required.

If a heat treatment at 1500° C. or higher is performed while the surface of the SiC epitaxial layer 14 is exposed, the P-type dopant species diffuses out and degradation in electrical characteristic occurs. It is, therefore, preferable to cap, before annealing, the surface of the SiC epitaxial layer 14 with the carbon protective film 13 formed of graphite, because the carbon protective film 13 formed of graphite can endure even the heat treatment at 1500° C. or higher.

As a method for forming the carbon protective film 13, film forming using plasma or film forming by low-pressure CVD may be mentioned. From the viewpoint of performing annealing at a high temperature equal to or higher than 1500° C., it is preferable to use low-pressure CVD for forming the carbon protective film 13 on each of the front and back surfaces of the SiC wafer 10 in order to avoid application of stress to the protective film.

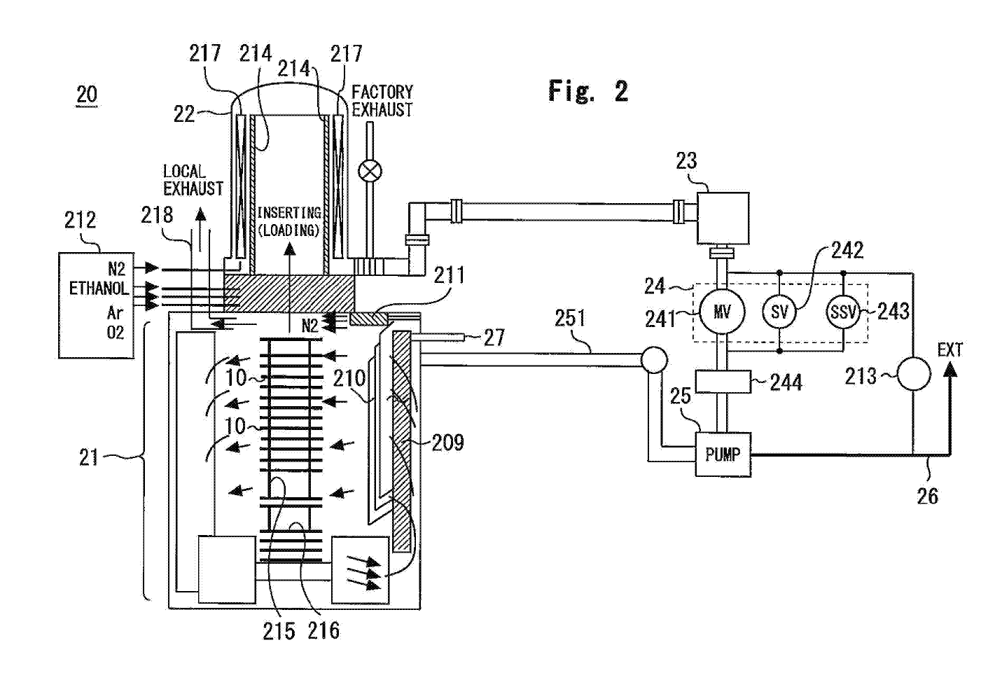

FIG. 2 is a diagram showing a semiconductor annealing apparatus 20 according to an embodiment of the present invention. After the carbon protective film 13 has been formed on the front and back surfaces of the SiC wafer 10, annealing is performed in a high-temperature furnace at 1500° C. or higher and the carbon protective film 13 is thereafter removed in an oxygen plasma atmosphere. With one semiconductor annealing apparatus 20, this sequence of steps can be performed. An improvement in quality can therefore be achieved by reducing the number of steps, improving the productivity and reducing inter-step-environment-derived foreign materials.

The semiconductor annealing apparatus 20 is specified as a vertical decompression type suitable for inhibiting involved oxidation. The semiconductor annealing apparatus 20 has a loading area 21, which is a transport chamber having airtightness, and a chamber 22 provided above the loading area 21. The semiconductor annealing apparatus 20 has a trap 23 which communicates with the chamber 22, a valve group 24 which communicates with the trap 23, a dust trap 244 which communicates with the valve group 24, a pump 25 which communicates with the dust trap 244, and exhaust piping 26 which branches off from the pump 25. The semiconductor annealing apparatus 20 has a nitrogen introduction port 27 projecting out of the loading area 21, a side filter 209 which communicates with the nitrogen introduction port 27, flow straightening plates 210 which straighten a flow of nitrogen having passed through a side filter 209, and a nitrogen shower 211 which causes nitrogen to flow horizontally at the boundary between the loading area 21 and the chamber 22. The semiconductor annealing apparatus 20 has a gas system 212, an atmospheric pressure return valve 213, a tube 214 provided in the chamber, a wafer boat 215 capable of advancing into and retreating out of the tube 214, a pedestal 216 which is made of quartz, and on which the wafer boat 215 is mounted, and a heater 217 disposed outside the tube 214. While a section of the tube 214 is illustrated in FIG. 2, the tube 214 is actually a tubular or hollow and cylindrical and the wafer boat 215 can be housed in a space therein. The tube 214 is not necessarily cylindrical. The tube 214 may have any other sectional shape, e.g., an elliptical or rectangular shape. The interior of the chamber 22 communicates with the trap 23 through piping. The trap 23, the valve group 24, the dust trap 244 and the pump 25 communicate one with another in this order. The pump 25 communicates with the loading area 21 through piping. The atmospheric pressure return valve 213 selectively provides communication between the exhaust piping 26 and the upstream side of the valve group 24. The semiconductor annealing apparatus 20 has a local exhaust tube 218. One end of the local exhaust tube 218 is provided at the boundary between the loading area 21 and the chamber 22. The local exhaust tube 218 extends to such an extent that its other end is located outside the semiconductor annealing apparatus 20. In the present embodiment, the one end of the local exhaust tube 218 is positioned opposite from the nitrogen shower 211.

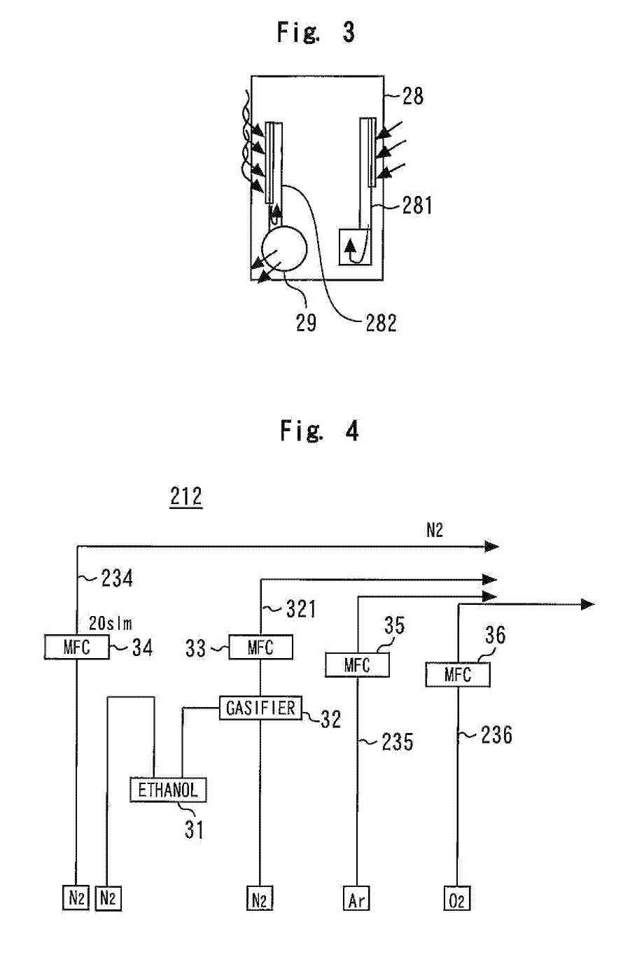

FIG. 3 illustrates a back door 28 of the semiconductor annealing apparatus 20. The semiconductor annealing apparatus 20 has a back surface which faces a back side in FIG. 2, and the back door 28 is a part provided in the back surface. An exhaust port 29, a suction port 281 and an intake port 282 are provided in the back door 28.

When the semiconductor annealing apparatus 20 is used, the SiC wafer 10 is first transported into the loading area 21 and moved into the wafer boat 215 in the loading area 21. The wafer boat 215 is thereafter inserted in the chamber 22. An operation to set the SiC wafer 10 in the wafer boat 215 is called “charging”. An operation to insert in the chamber 22 the wafer boat 215 in which the SiC wafer 10 is set is called “loading”.

The structure on the exhaust side will be described. A product in exhaust gas is removed by cooling the exhaust gas in the trap 23, and the exhaust gas is discharged from the exhaust piping 26 via the pump 25. The valve group 24 is used for evacuation from atmospheric pressure to a reduced pressure. The valve group 24 includes a main valve (MV) 241, a sub-valve (SV) 242 and a sub-sub-valve (SSV) 243. The provision of the SV 242 and the SSV 243 in addition to the MV 241 enables slow evacuation for prevention of foreign material dust generation. The wafer boat 215 is inserted inside the tube 214, followed by evacuation. A gas is thereafter introduced through the gas system 212 and forming of the carbon protective film 13, which is graphite film, annealing and processing for removing the carbon protective film 13 are performed in this order. To enable processing at a reduced pressure before a temperature of 1000° C. is reached, a sufficiently large distance is provided from the lower outlet/inlet of the semiconductor annealing apparatus 20 to a region on the periphery of the chamber 22 for product processing. The temperature around the outlet/inlet is reduced with a heat shielding plate (not shown in Drawings), thereby maintaining sealing performance. The semiconductor annealing apparatus 20 has the gas system 212 shown in FIG. 4 and described later. Ethanol is gasified by a gasifier 32.

The loading area 21 is constructed as an enclosed transport chamber and is made capable of nitrogen substitution in the loading area 21. This is performed for the purpose of inhibiting involved oxidation when the wafer boat 215 is inserted in the tube 214.

The tube 214 and the wafer boat 215 are made of SiC and are made by all-CVD. Heat resistance under a high temperature of 1500° C. or higher is thereby secured to avoid damage at the time of removal of the carbon protective film 13. In the process according to “all-CVD”, SiC film is formed by CVD on the surface of the carbon basic material and burning and disappearance of the carbon basic material are caused simultaneously with forming of the SiC coating film in the step of forming the SiC coating film, thus enabling obtaining the structural members formed only of the SiC CVD film.

If the tube 214 and the wafer boat 215 are formed of quartz, the heat resistance is not sufficiently high under a temperature of 1400° C. or higher. If the tube 214 and the wafer boat 215 are formed of carbon, the carbon jigs themselves are etched when the carbon protective film 13 is removed after annealing.

In the present embodiment, quartz or carbon is not used for the tube 214 and the wafer boat 215, and the problem with them can therefore be avoided. That is, the tube 214 and the wafer boat 215 are formed only of SiC film of a high purity formed by using all-CVD. Contamination can therefore be prevented even in a high temperature region of 1400° C. or higher. The present invention, however, is not limited to this. The tube 214 and the wafer boat 215 may be members made of sapphire. The materials of the tube 214 and the wafer boat 215 may be different from each other. One of the tube 214 and the wafer boat 215 may be a member made of sapphire and the other may be a member made of SiC and formed by all-CVD. Conditions for heat resistance under a high temperature and prevention of damage at the time of removal of graphite are thus achieved.

There is a strong possibility of atmospheric air entering the chamber 22 to cause oxidation while the wafer boat 215 is being inserted into the space inside the tube 214. If oxide film generated by involved oxidation is mixed in the interface with the SiC wafer 10, a fault is caused. More specifically, if oxide film caused by involved oxidation intervenes when the carbon protective film 13 is formed on the SiC wafer 10 in the activation annealing step, the oxide film (SiO film) is molten by annealing at 1500° C. or higher thereafter performed, resulting in separation of the carbon protective film 13.

In the semiconductor annealing apparatus 20, the nitrogen introduction port 27 is provided in the loading area 21 for the purpose of preventing the occurrence of involved oxidation, and enables substitution of nitrogen in the loading area 21. By performing nitrogen substitution before insertion of the wafer boat 215, the atmospheric components in the loading area 21 are reduced to zero, thus enabling inhibition of involved oxidation. Preferably, after nitrogen substitution at 600° C., the wafer boat 215 is inserted in the tube 214. Involved oxidation can be inhibited in this way. From the viewpoint of further inhibiting involved oxidation, it is preferable to quickly load the wafer boat 215 in the tube 214 by setting the wafer boat 215 insertion speed to 500 mm/min or higher. Since substitution of nitrogen in the loading area 21 is performed, a structure in which the back door 28, for example, is sealed with an O-ring is adopted to prevent nitrogen from flowing out of the semiconductor annealing apparatus 20.

After the wafer boat 215 is loaded inside the tube 214, vacuum substitution is performed and the temperature is increased to 1000° C. Gasified ethanol is introduced in this temperature zone and the carbon protective film 13, which is graphite film, is formed. After the film forming, atmospheric pressure substitution of Ar is performed and annealing on the SiC wafer 10 at a temperature of 1500° C. or higher is performed. Because the carbon protective film 13 is formed on the front and back surfaces of the SiC wafer 10 by CVD at 1000° C., the surface of the carbon protective film 13 is not deteriorated even by high-temperature annealing, for example, at about 1950° C.

After annealing, the temperature is reduced to 850° C. in the Ar atmosphere. At the stage at 850° C., the gas supplied from the gas system 212 is changed to oxygen gas. The carbon protective film 13 attached to the SiC wafer 10, the tube 214 and the wafer boat 215 is removed, the wafer boat 215 is drawn out of the tube 214 at a temperature of 800° C. or less, and the SiC wafer 10 is taken out.

It is preferable, in consideration of removal of the carbon protective film 13, to form a quartz member as an inner lower portion of the tube 214 so that the surface formed of SUS is not exposed. This is because if the SUS surface is exposed at the time of removal with oxygen gas, rust is generated from the exposed portion to cause contamination inside the tube 214. It is desirable, for example, to avoid disposing a wafer boat rotation mechanism below the wafer boat 215 for avoidance of this contamination. The wafer boat rotation mechanism is a mechanism for improving the uniformity of film forming in the wafer surface, and sealing for the mechanism is performed, for example, by using a ceramic seal.

In the case of a semiconductor annealing apparatus in which only deposition is repeated, there is a need to perform a cleaning operation for every fifteen batches, for example, because the reproducibility of the film thickness value is reduced. In contrast, in the semiconductor annealing apparatus 20, forming and removal of the carbon protective film 13 are alternately performed and, therefore, the film thickness stability of the carbon protective film 13 can be improved without requiring the maintenance time in the case of performing only deposition. Further, the number of cycles in which the temperature is increased and reduced can be reduced from 6 to 2 by combining the three steps into a continuous process, thus enabling moderation of thermal stress on the SiC wafer 10.

The process including forming of the carbon protective film 13 which is a film for protection in the activation annealing step, high-temperature annealing, and removal of the carbon protective film 13 after the annealing step is performed with one apparatus. As the results of this, a reduction in the number of process steps, an improvement in productivity and an improvement in quality achieved by reducing inter-step-environment-derived foreign materials can be expected.

The semiconductor annealing apparatus 20 has the nitrogen shower 211. The nitrogen shower 211 is capable of applying nitrogen in a sidewise direction intersecting the direction of advancement of the wafer boat 215 during loading of the wafer boat 215. Since the nitrogen shower 211 can apply nitrogen in a sidewise direction to a plurality of SiC wafers 10 arranged on the wafer boat 215, nitrogen gas flows by passing through spaces between the plurality of SiC wafers 10. The atmospheric components between the plurality of SiC wafers 10 arranged on the wafer boat 215 can thereby be inhibited from mixing inside the tube 214. Surface foreign materials attached to the surfaces of the SiC wafers 10 can also be removed. The present invention is not limited to this. The nitrogen shower 211 may be disposed at any other angle and in any other position.

It is not preferable, in terms of safety, to maintain, after the completion of film forming, the interior of the loading area 21 in the same condition as that after nitrogen substitution. It is, therefore, preferable to enable atmospheric air substitution by taking in atmospheric air, for example, through the intake port 282 provided in the back door 28 at the back of the loading area 21 and by feeding the atmospheric air into the loading area 21 via the side filter 209 and the flow straightening plates 210.

There is a possibility of the surface of the SiC wafer 10 adsorbing water, and there is an apprehension that the water may evaporate to cause oxidation of the surface of the SiC wafer 10 when the wafer boat 215 is inserted inside the tube 214. A preferred form of the present embodiment is therefore conceivable in which piping 251 from the loading area 21 to the pump 25 is provided to enable vacuum substitution in the loading area 21.

Further, to inhibit the involved oxidation, there is also an apprehension about residual oxide inside the tube 214 and it is, therefore, preferable to introduce nitrogen at a flow rate of 20 slm or higher from nitrogen gas piping 234 in the gas system 212 while the wafer boat 215 is being inserted. Oxygen is thereby inhibited from remaining inside the tube 214, thus reliably inhibiting involved oxidation during insertion of the wafer boat 215.

FIG. 4 is a diagram schematically showing the gas system 212 of the semiconductor annealing apparatus 20. The structure of the gas system 212 for stabilizing the deposition rate in the semiconductor annealing apparatus 20 will be described below. The gas system 212 includes an ethanol tank 31, the gasifier 32, mass-flow controllers (MFC) 33, 34, 35, and 36, the nitrogen gas piping 234, carrier gas piping 235, and oxygen gas piping 236. In the ethanol tank 31, liquid ethanol provided as a carbon protective film 13 forming source is stored. The gasifier 32 communicates with the ethanol tank 31 and can gasify ethanol in liquid form. The MFC 33 communicates with the gasifier 32 and performs flow rate control on gasified gas from the gasifier 32. The nitrogen gas piping 234 is capable of supplying nitrogen gas for inhibiting involved oxidation. The carrier gas piping 235 is capable of supplying a carrier gas for feeding gasified ethanol. In the present embodiment, this carrier gas is Ar. Ethanol in liquid form in the ethanol tank 31 is fed in the liquid state into the gasifier 32, and nitrogen gas is blown to the gasifier 32 to gasify the ethanol. For prevention of liquefaction, at this time, it is preferable to temperature-control piping 321 from the gasifier 32 to the chamber 22 to 40±1° C. by using temperature control means not illustrated. The rate of flow of the gasified ethanol is controlled with the MFC 33. The gasified ethanol gas introduced into the chamber 22 can thereby be caused to flow at a constant flow rate while being prevented from liquefying, thus enabling stabilization of the deposition rate.

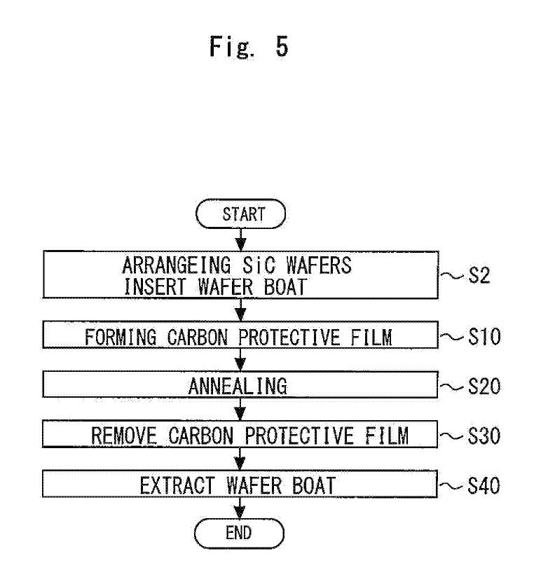

FIG. 5 is a flowchart showing a process in a semiconductor annealing method according to the embodiment of the present invention.

First, in step S2, SiC wafers 10 are arranged on the wafer boat 215 and the wafer boat 215 is inserted (that is, loaded) inside the tube 214. When the wafer boat 215 is inserted inside the tube 214, nitrogen is supplied from the nitrogen introduction port 27 and the nitrogen shower 211 into the loading area 21 via the flow straightening plates 210 so as to inhibit forming of oxide film on the SiC wafers 10 by involved oxidation. The oxygen concentration is thereby reduced preferably to a value on the order of several ppm. Thereafter, the wafer boat 215 is inserted inside the tube 214. Involved oxidation on the surface of the SiC wafers 10 can thereby be inhibited.

The temperature inside the tube 214 when the wafer boat 215 is inserted inside the tube 214 is preferably 400 to 600° C. The reason for setting the lowest temperature to 400° C. is that there is an apprehension of separation of the carbon protective film 13 at a temperature not higher than 400° C. The reason for setting the highest temperature to 600° C. is that there is a risk of the SiC wafers 10 being heat-cracked by being thermally stressed abruptly when the temperature is equal to or higher than 600° C.

Subsequently, in step S10, forming of the carbon protective film 13 is performed. After the wafer boat 215 has been inserted inside the tube 214, the pressure inside the tube 214 is evacuated to a reduced pressure by the pump 25 upon opening the main valve (MV) 241. Thereafter, the temperature inside the tube 214 is increased preferably to about 1000° C. and gasified ethanol gas is introduced. Liquid ethanol is gasified by the gasifier 32 in the gas system 212 shown in FIG. 4, and is introduced into the tube 214 while being flow-rate-controlled by the mass-flow controller (MFC) 33, thereby enabling the carbon protective film 13, which is graphite film, to be formed. At this point in time, the SiC wafers 10 capped with the carbon protective film 13 as shown in FIG. 1 are completed.

In a preferred mode of the present embodiment, vacuum substitution is performed after loading of the wafer boat 215 and the temperature is increased to 900 to 1000° C. Gasified ethanol is introduced in this temperature zone and the carbon protective film 13 is formed. The reason for setting the temperature range to 900 to 1000° C. is that in this temperature range the uniformity of the film thickness in the surfaces of the SiC wafers 10 can be made within 8%. This temperature range setting is preferably used to secure the film thickness uniformity in a case where the wafer boat rotation mechanism is not disposed for the above-mentioned contamination prevention by avoiding exposure of the SUS surface.

After forming of the carbon protective film 13 at about 1000° C., Ar gas is introduced from the carrier gas piping 235 to perform substitution of Ar gas, and a purge is performed for 10 minutes or longer, thereby achieving an atmospheric-pressure atmosphere condition with Ar gas.

The process thereafter advances to step S20 and annealing is performed. From the Ar atmospheric-pressure atmosphere at 1000° C., the temperature inside the tube 214 is further increased at a temperature rise rate of about 100° C/min. A temperature of 1500° C. or higher, preferably 1600° C. or higher is thereby reached and annealing is performed.

Subsequently, in step S30, the carbon protective film 13 is removed. Details of step S30 will be described. First, after the completion of annealing in step S20, the temperature inside the tube 214 is reduced preferably to 850 to 900° C. After lowering the temperature, the pressure inside the tube 214 is again evacuated to a reduced pressure and the operation to remove the carbon protective film 13 is started. Switch from Ar gas supply from the carrier gas piping 235 to oxygen gas supply from the oxygen gas piping 236 is performed and oxygen gas is introduced into the tube 214. The carbon protective film 13 formed on the SiC wafers 10 is thereby caused to react with oxygen to be removed. The carbon protective film 13 attached to the tube 214 and the wafer boat 215 can simultaneously be removed.

Subsequently, in step S40, extraction (unloading) of the wafer boat 215 is performed. After removal of the carbon protective film 13, the temperature is reduced preferably to 800° C. or lower and the pressure inside the tube 214 is returned to atmospheric pressure with nitrogen gas. Thereafter, the wafer boat 215 is drawn out of the tube 214 (that is, unloaded) and the SiC wafers 10 are taken out. The SiC wafers 10 may be taken out in atmospheric air without nitrogen substitution since there is no apprehension of oxidation of the SiC wafers 10 when the SiC wafers 10 are taken out.

The first technical feature of the semiconductor annealing apparatus 20 according to the present embodiment resides in that the tube 214 and the wafer boat 215 are made of SiC and formed by all-CDV in order to prevent contamination caused by high-temperature annealing. The second technical feature of the semiconductor annealing apparatus 20 according to the present embodiment resides, for example, in the idea of forming the loading area 21 as an enclosed transport chamber capable of nitrogen substitution, and the idea of providing the nitrogen shower 211, for prevention of involved oxidation. According to the present invention, however, both the first and second technical features are not necessarily used always in combination. Only the first technical feature may be used for the semiconductor annealing apparatus 20 to prevent contamination caused by high-temperature annealing, and the components for nitrogen substitution may be removed. Only the second technical feature may alternatively be used for the semiconductor annealing apparatus 20 to inhibit involved oxidation, and the tube 214 and the wafer boat 215 may be the same as conventional ones.

### REFERENCE SIGNS LIST

10 silicon carbide (SiC) wafer

11, 12 P-type implanted layer

13 carbon protective film (graphite film)

14 SiC epitaxial layer

15 substrate

20 semiconductor annealing apparatus

21 loading area

22 chamber

23 trap

24 valve group

25 pump

251 piping

26 exhaust piping

27 nitrogen introduction port

28 back door

29 exhaust port

31 ethanol tank

32 gasifier

33, 34, 35, 36 MFC (mass-flow controllers)

234 nitrogen gas piping

235 carrier gas piping

236 oxygen gas piping

209 side filter

210 straightening plates

211 nitrogen shower

212 gas system

213 atmospheric pressure return valve

214 tube

215 wafer boat

216 pedestal

217 heater

218 local exhaust tube

241 main valve

242 sub-valve

243 sub-sub-valve

244 dust trap

281 suction port

282 intake port

321 piping

1. A semiconductor annealing apparatus comprising:
a chamber;
a tube provided inside the chamber;
a wafer boat provided inside the tube so as to be able to advance into and retreat out of the tube;
a loading area in which the wafer boat is positioned when the wafer boat retreats out of the tube;
a hydrocarbon supplier for supplying hydrocarbon gas into the tube;
a heater for heating the inside of the tube; and
an oxygen supplier for supplying oxygen into the tube,
wherein the tube is made of sapphire or is made of SiC and formed by all-CVD, and
wherein the wafer boat is made of sapphire or is made of SiC and formed by all-CVD.

2. The semiconductor annealing apparatus according to claim 1, further comprising a nitrogen introducer for performing substitution of nitrogen inside the loading area.

3. The semiconductor annealing apparatus according to claim 1, further comprising a nitrogen shower which causes nitrogen gas to flow so as to intersect a direction of advancement of the wafer boat from the loading area toward the tube.

4. The semiconductor annealing apparatus according to claim 3, wherein the nitrogen shower is provided at a boundary between the loading area and the tube.

5. The semiconductor annealing apparatus according to claim 1, further comprising:
piping connecting to the loading area; and
a vacuum pump connected to the piping.

6. The semiconductor annealing apparatus according to claim 1, further comprising a pedestal provided in the loading area, the pedestal supporting the wafer boat at a side opposite from the tube, wherein the pedestal is formed of quartz.

7. The semiconductor annealing apparatus according to claim 1, wherein the heater is controlled so that the temperature inside the chamber is in a range from 400 to 600° C. when the wafer boat is inserted inside the chamber.
